(19) United States
(12) Patent Application Publication
(10) Pub. No.: US 2026/0363027 A1
(43) Pub. Date: Nov. 12, 2026

(54) TESTING CIRCUIT AND TESTING METHOD

(71) Applicant: TAIWAN SEMICONDUCTOR MANUFACTURING COMPANY, LTD., Hsinchu (TW)

(72) Inventors: Devan Rickey Peters, Hsinchu (TW); Shuo-Wen CHANG, Hsinchu (TW); Chu-Feng LIAO, Hsinchu (TW); Yuan-Yao CHANG, Hsinchu (TW)

(73) Assignee: TAIWAN SEMICONDUCTOR MANUFACTURING COMPANY, LTD., Hsinchu (TW)

(21) Appl. No.: 19/201,109

(22) Filed: May 7, 2025

(51) Int. Cl. H10P 74/20; H03K 19/003

(52) U.S. Cl. CPC H10P 74/207; H03K 19/00315

(57) ABSTRACT

A testing circuit and a testing method f are provided. The testing circuit includes a PMOS path, a NMOS path, a first selection logic circuit, a CMOS path and a second selection logic circuit. The first selection logic circuit is connected to the PMOS path and the NMOS path. The first selection logic circuit is used to select either the PMOS path or the NMOS path. The second selection logic circuit is connected to the CMOS path. The second selection logic circuit is used to enable or disable the CMOS path.

### BACKGROUND

The disclosure relates in general to a circuit and a manufacturing process, and more particularly to a testing circuit and a testing method.

In semiconductor manufacturing, testing procedure, such as Wafer Acceptance Test (WAT) is essential to ensure the quality and performance of the fabricated devices before further processing. For example, the WAT helps verify whether the semiconductor fabrication process meets design specifications and manufacturing standards. It checks for defects, variations, and abnormalities in the process. The WAT measures key electrical parameters such as resistance, capacitance, and transistor characteristics to ensure that the devices meet functional requirements. By identifying defective wafers early, WAT allows manufacturers to analyze and address process issues, leading to improved production yield and efficiency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a testing circuit according to one embodiment of the present disclosure.

FIG. 2 shows a D-flip flop.

FIG. 3 shows an inverter and a first selection logic circuit according to one embodiment of the present disclosure.

FIG. 4 shows a CMOS transmission gate.

FIG. 5 shows a second selection logic circuit.

FIG. 6 shows a flowchart of a testing method for a semiconductor device according to one embodiment of the present disclosure.

FIGS. 7A to 7D illustrate the steps in the FIG. 6.

FIG. 8 shows a flowchart of a testing method for the semiconductor device according to another embodiment of the present disclosure.

FIGS. 9A to 9D illustrate the steps in the FIG. 8.

FIG. 10 shows a flowchart of a testing method for the semiconductor device according to another embodiment of the present disclosure.

FIGS. 11A to 11D illustrate the steps in the FIG. 10.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

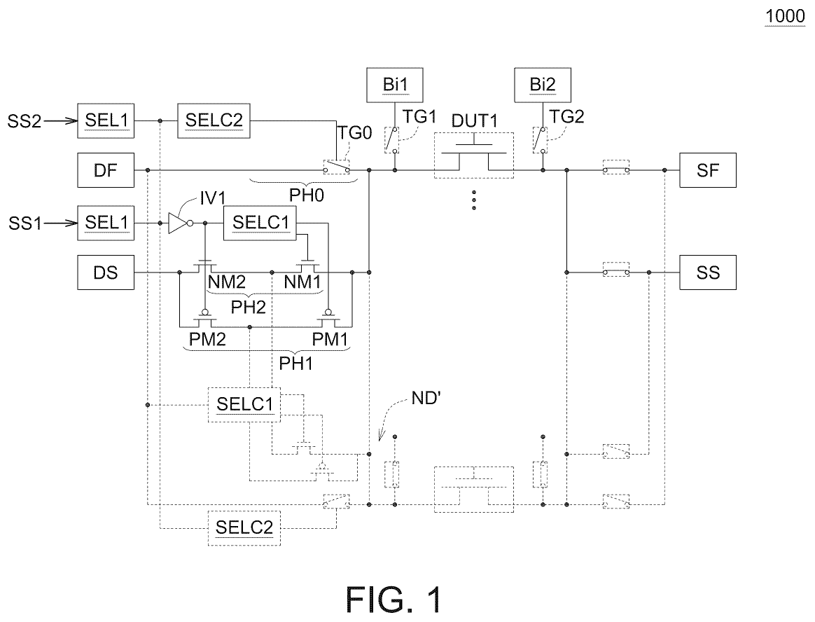

Please refer to FIG. 1, which shows a testing circuit 1000 according to one embodiment of the present disclosure. The testing circuit 1000 is a multi-path adaptive switching (MPAS) device for Advanced Process Control Monitor (APCM). In the semiconductor manufacturing, Wafer Acceptance Test (WAT) is a key stage in semiconductor manufacturing that ensures the wafer meets quality and performance standards before moving forward in the production process. During this stage, the APCM helps ensure the proper functioning of test equipment and improves the reliability and accuracy of the tests conducted on the wafer.

The key functions of the APCM in the WAT test line circuitry includes, for example, real-time monitoring, process stability, data analysis and feedback, prevention of test failures and/or optimization of testing efficiency. For example, the APCM system monitors the test line circuitry in real-time to track the behavior of key parameters such as voltage, current and signal integrity. Any deviation from the expected parameters is flagged, enabling timely corrections or alerts to prevent test errors.

By maintaining stability in the test environment, the APCM helps ensure that the WAT measurements (such as electrical tests, signal tests, or functional tests) are accurate and consistent across all wafers being tested. Stability in the testing process is crucial for evaluating the performance of the wafer under real-world conditions.

The APCM collects and analyzes data from the WAT test line circuitry, identifying trends, abnormalities, and potential failures. This feedback is used to adjust the test equipment or make fine-tuned changes to the test parameters for more precise measurements and improved yield.

Since the WAT is often the final opportunity to detect faults or defects before moving forward with the wafer, the APCM can help prevent test failures by continuously monitoring the test line circuitry for any signs of issues that may affect test results or accuracy.

By automatically adjusting the test line parameters based on real-time data and historical performance, the APCM can optimize the test cycle, improving throughput while maintaining high quality. This also helps in reducing downtime and inefficiencies caused by manual adjustments.

The applications of the APCM includes, for example, signal integrity monitoring, test equipment calibration and/or yield improvement. For example, the APCM ensures that signal integrity is maintained during testing, especially for high-frequency or high-speed circuits on the wafer. The APCM assists in calibrating test equipment in real-time, ensuring that the tools used in the WAT are functioning at peak performance. By optimizing test conditions and minimizing test variations, the APCM can improve the overall yield of wafers that pass the acceptance testing.

In essence, the APCM in the WAT test line circuitry is essential for maintaining high-quality standards, ensuring accurate and reliable testing, and preventing defects from progressing further into the manufacturing process.

As shown in the FIG. 1, the test circuit 1000 includes a PMOS path PH1, a NMOS path PH2, an inverter IV1, a first selection logic circuit SELC1, a CMOS path PH0, a second selection logic circuit SELC2, two biasing transmission gates TG1, TG2, and a plurality of pads DS, SEL1, DF, SEL2, Bi1, Bi2, SF, SS. The PMOS path PH1 is connected to the semiconductor device DUT1. The semiconductor device DUT1 is the device under test. The NMOS path PH2 is connected to the semiconductor device DUT1. The first selection logic circuit SELC1 is connected to the PMOS path PH1 and the NMOS path PH2. The CMOS path PH0 is connected to the semiconductor device DUT1. The second selection logic circuit SELC2 is connected to the CMOS path PH0.

The first selection logic circuit SELC1 connected to the PMOS path PH1 and the NMOS path PH2 is used to select either the PMOS path PH1 or the NMOS path PH2. For example, in one embodiment, the first selection logic circuit SELC1 could enable the PMOS path PH1 and disable the NMOS path PH2. In another embodiment, the first selection logic circuit SELC1 could disable the PMOS path PH1 and enable the NMOS path PH2.

As shown in the FIG. 1, the PMOS path PH1 includes a local PMOS transistor PM1 and a global PMOS transistor PM2. The local PMOS transistor PM1 is coupled to an output end of the first selection logic circuit SELC1. The global PMOS transistor PM2 is coupled to an input end of the first selection logic circuit SEL1. The local PMOS transistor PM1 and the global PMOS transistor PM2 are connected in series.

The inverter IV1 connected to the first selection logic circuit SELC1 receives a first selection signal SS1 through the pad SEL1 to select the PMOS path PH1 or the NMOS path PH2.

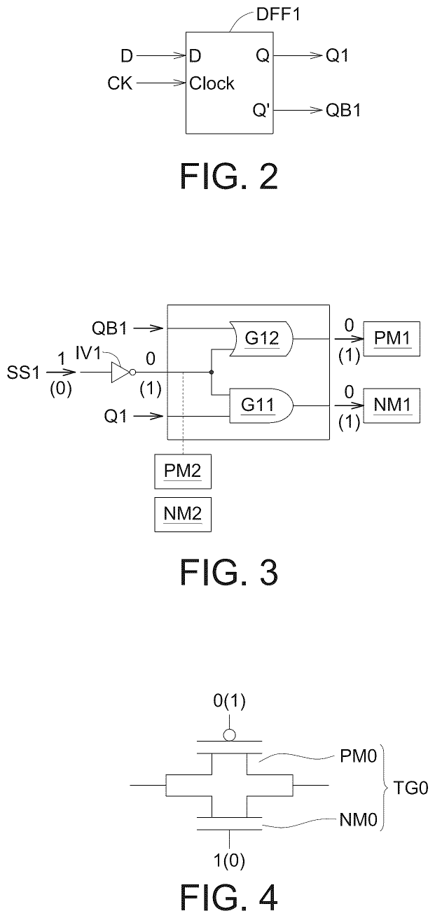

Please refer to FIG. 2, which shows a D-flip flop DFF1. The D-flip flop DFF1 is a type of sequential logic circuit used to store a single bit of data. It is a fundamental component in digital electronics, commonly used in registers, counters, and memory devices. The D-flip flop DFF1 captures the value of an input signal D at the moment when a clock pulse CK occurs and stores it until the next clock event. It is edge-triggered, meaning it responds to either the rising edge (positive edge) or falling edge (negative edge) of the clock signal CK. When a clock pulse occurs, the value at the input signal D is transferred to a primary output signal Q1. A complementary output signal QB1 is always the complement of the primary output signal Q1.

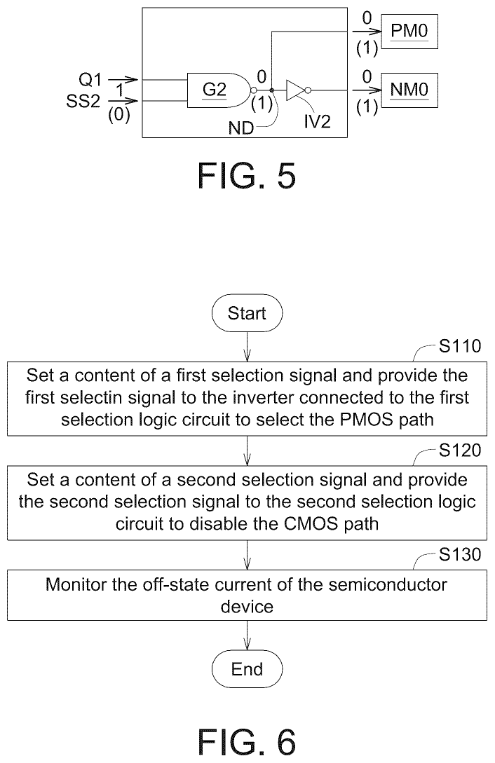

Please refer to FIG. 3, which shows the inverter IV1 and the first selection logic circuit SELC1 according to one embodiment of the present disclosure. The first selection logic circuit SELC1 includes an AND gate G11 and an OR gate G12. One input end of the AND gate G11 is used to receive the primary output signal Q1 from the D-flip flop DFF1. Another input end of the AND gate G11 is connected to the inverter IV1. An output end of the AND gate G11 is connected to the local NMOS transistor NM1 of the NMOS path PH2. One input end of the OR gate G12 is used to receive the complementary output signal QB1 from the D-flip flop DFF1. Another input end of the OR gate G12 is connected to the inverter IV1. An output end of the OR gate G12 is connected to the local PMOS transistor PM1 of the PMOS path PH1.

As shown in the FIG. 3, if the first selection signal SS1 is “1”, “0” would provide to the local PMOS transistor PM1 and the global PMOS transistor PM2 of the PMOS path PH1, and “0” would provide to the local NMOS transistor NM1 and the global NMOS transistor NM2 of the NMOS path PH2. As such, the PMOS path PH1 would be enabled, and the NMOS path PH2 would be disabled.

As shown in the FIG. 3, if the first selection signal SS1 is “0” (shown in brackets), “1” (shown in brackets) would provide to the local PMOS transistor PM1 and the global PMOS transistor PM2 of the PMOS path PH1, and “1” (shown in brackets) would provide to the local NMOS transistor NM1 and the global NMOS transistor NMOS transistor NM2 of the NMOS path PH2. As such, the PMOS path PH1 would be disabled, and the NMOS path PH2 would be enabled.

As shown in the FIG. 1, the second selection logic circuit SELC2 receives a second selection signal SS2 through the pad SEL2 to enable or disable the CMOS path PH0.

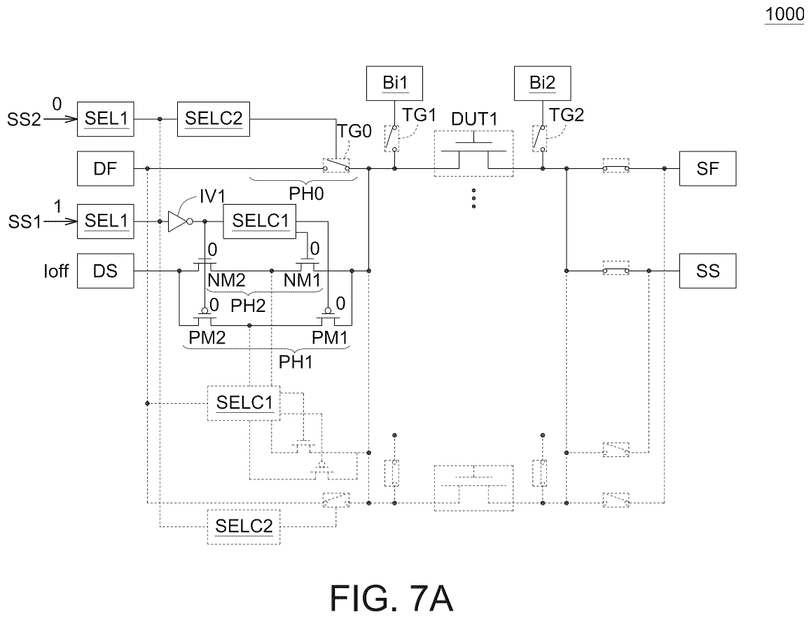

As shown in the FIG. 1, the CMOS path PH0 includes a CMOS transmission gate TG0. The CMOS transmission gate TG0 is connected to the second selection logic circuit SELC2 and the semiconductor device DUT1. Please refer to FIG. 4, which shows the CMOS transmission gate TG0. The CMOS transmission gate TG0 includes a PMOS transistor PM0 and a NMOS transistor NM0. The PMOS transistor PM0 and the NMOS transistor NM0 are connected in parallel.

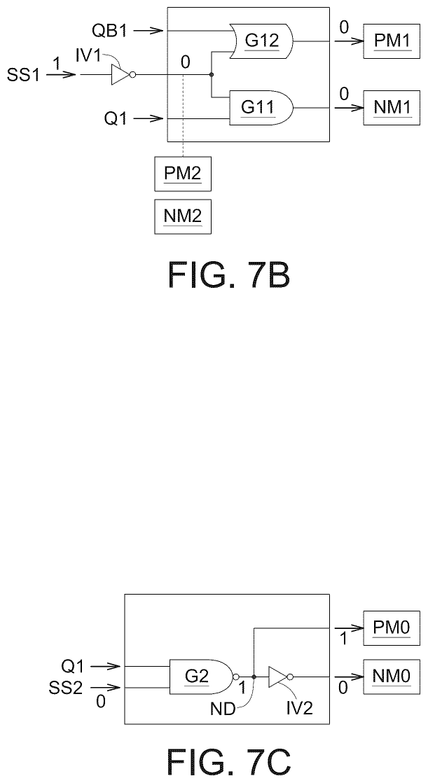

Please refer to FIG. 5, which shows the second selection logic circuit SELC2. The second selection logic circuit SELC2 includes a NAND gate G2 and an inverter IV2. One input end of the NAND gate G2 is used to receive the primary output signal Q1 from the D-flip flop DFF1. Another input end of the NAND gate G2 is used to receive the second selection signal SS2. An input end of the inverter IV2 is connected to an output end of the NAND gate G2. An output end of the inverter IV2 is connected to the NMOS transistor NM0 of the CMOS transmission gate TG0. A node ND between the NAND gate G2 and the inverter IV2 is connected to the PMOS transistor PM0 of the CMOS transmission gate TG0.

As shown in the FIG. 5, if the second selection signal SS2 is “1”, “0” would provide to the PMOS transistor PM0 of the CMOS path PH0 and “1” would provide to the NMOS transistor NM0 of the CMOS path PH0. As such, the CMOS path PH0 is enabled.

As shown in the FIG. 5, if the second selection signal SS2 is “0” (shown in brackets), “1” (shown in brackets) would provide to the PMOS transistor PM0 of the CMOS path PH0 and “0” (shown in brackets) would provide to the NMOS transistor NM0 of the CMOS path PH0. As such, the CMOS path PH0 is disabled.

The testing circuit 1000 could be used to monitor different characteristics of the semiconductor device DUT1. The following describes the testing methods for various characteristics.

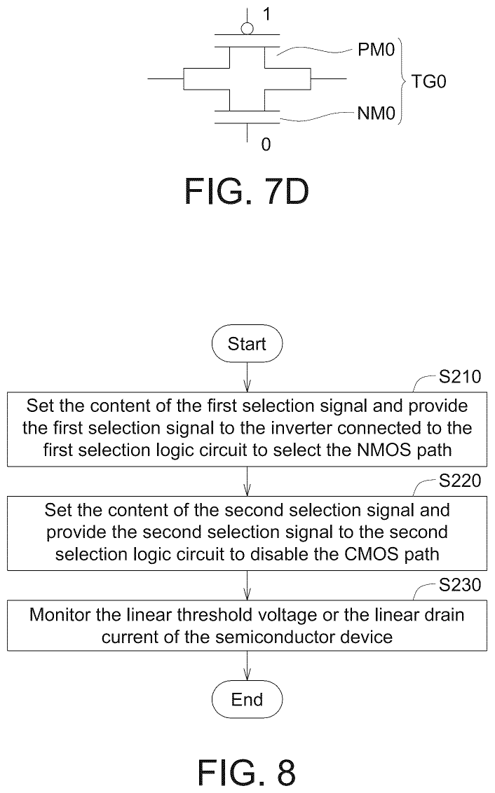

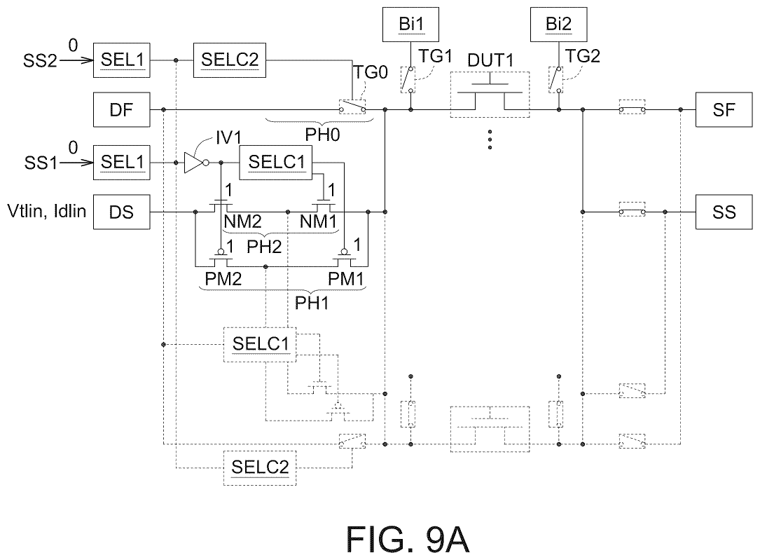

Please refer to FIG. 6 and FIGS. 7A to 7D. FIG. 6 shows a flowchart of a testing method for the semiconductor device DUT1 according to one embodiment of the present disclosure. FIGS. 7A to 7D illustrate the steps in the FIG. 6. The testing method for the semiconductor device 1000 includes, for example, step S110 to S130.

In the step S110, as shown in the FIGS. 7A and 7B, a content of the first selection signal SS1 is set and the first selectin signal SS1 is provided to the inverter IV1 connected to the first selection logic circuit SELC1 to select the PMOS path PH1. For example, the first selection signal SS1 is set as “1”. Accordingly, “0” is provided to the local PMOS transistor PM1 and the global PMOS transistor PM2 of the PMOS path PH1, and “0” is provide to the local NMOS transistor NM1 and the global NMOS transistor NMOS of the NMOS path PH2. As such, the PMOS path PH1 is enabled, and the NMOS path PH2 is disabled.

Next, in the step S120, as shown in the FIGS. 7A, 7C and 7D, a content of the second selection signal SS2 is set and the second selection signal SS2 is provided to the second selection logic circuit SELC2 to disable the CMOS path PH0. For example, second selection signal SS2 is set as “0”. Accordingly, “1” is provided to the PMOS transistor PM0 of the CMOS path PH0 and “0” is provided to the NMOS transistor NM0 of the CMOS path PH0. As such, the CMOS path PH0 is disabled.

Then, in the step 130, as shown in the FIG. 7A, an off-state current Ioff of the semiconductor device 1000 is monitored. Since the PMOS transistors PM1 and PM2 of the PMOS path PH1 could effectively block the leakage currents, so the subthreshold leakage in the APCM could be avoided when the off-state current Ioff is monitored.

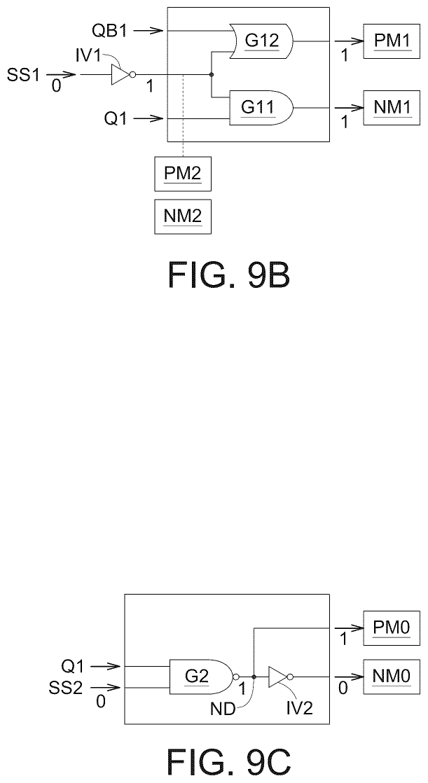

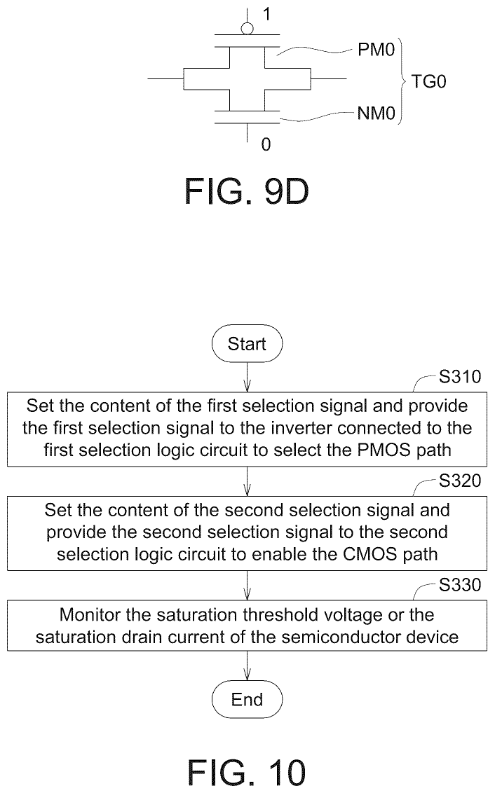

Please refer to FIG. 8 and FIGS. 9A to 9D. FIG. 8 shows a flowchart of a testing method for the semiconductor device DUT1 according to another embodiment of the present disclosure. FIGS. 9A to 9D illustrate the steps in the FIG. 8. The testing method for the semiconductor device 1000 includes, for example, step S210 to S230.

In the step S210, as shown in the FIGS. 9A and 9B, a content of the first selection signal SS1 is set and the first selectin signal SS1 is provided to the inverter IV1 connected to the first selection logic circuit SELC1 to select the NMOS path PH2. For example, the first selection signal SS1 is set as “0”. Accordingly, “1” is provided to the local PMOS transistor PM1 and the global PMOS transistor PM2 of the PMOS path PH1, and “1” is provide to the local NMOS transistor NM1 and the global NMOS transistor NMOS of the NMOS path PH2. As such, the PMOS path PH1 is disabled, and the NMOS path PH2 is enabled.

Next, in the step S220, as shown in the FIGS. 9A, 9C and 9D, a content of the second selection signal SS2 is set and the second selection signal SS2 is provided to the second selection logic circuit SELC2 to disable the CMOS path PH0. For example, second selection signal SS2 is set as “0”. Accordingly, “1” is provided to the PMOS transistor PM0 of the CMOS path PH0 and “0” is provided to the NMOS transistor NM0 of the CMOS path PH0. As such, the CMOS path PH0 is disabled.

Then, in the step 230, as shown in the FIG. 9A, a linear threshold voltage Vtlin or a linear drain current Idlin of the semiconductor device 1000 is monitored. Since the NMOS transistors NM1 and NM2 of the NMOS path PH2 could pass the low voltage to the semiconductor device DUT1, so the linear threshold voltage Vtlin or the linear drain current Idlin could be monitored in the APCM.

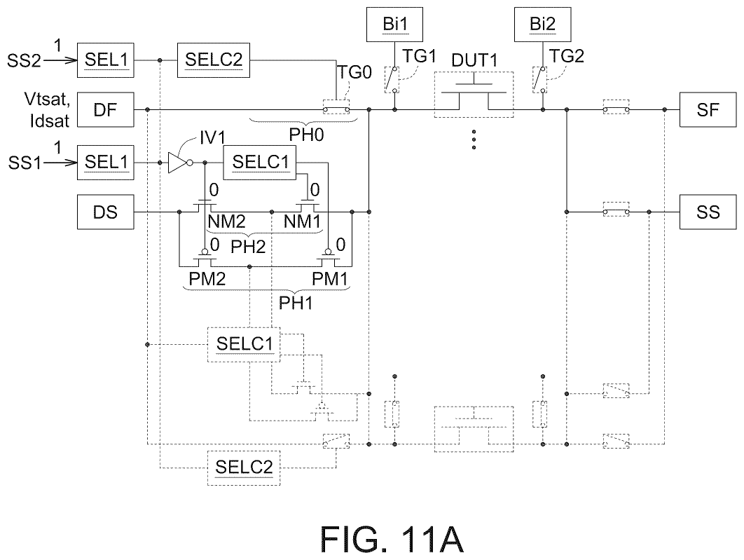

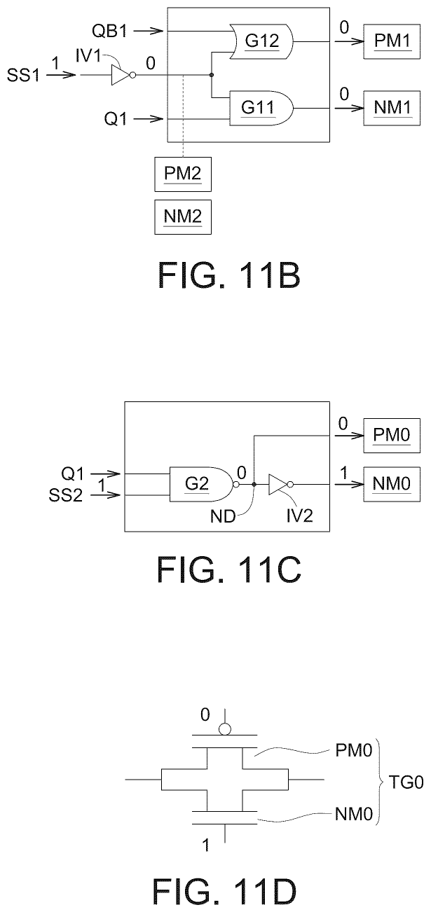

Please refer to FIG. 10 and FIGS. 11A to 11D. FIG. 10 shows a flowchart of a testing method for the semiconductor device DUT1 according to another embodiment of the present disclosure. FIGS. 11A to 11D illustrate the steps in the FIG. 10. The testing method for the semiconductor device 1000 includes, for example, step S310 to S330.

In the step S310, as shown in the FIGS. 11A and 11B, a content of the first selection signal SS1 is set and the first selectin signal SS1 is provided to the inverter IV1 connected to the first selection logic circuit SELC1 to select the PMOS path PH1. For example, the first selection signal SS1 is set as “1”. Accordingly, “0” is provided to the local PMOS transistor PM1 and the global PMOS transistor PM2 of the PMOS path PH1, and “0” is provide to the local NMOS transistor NM1 and the global NMOS transistor NMOS of the NMOS path PH2. As such, the PMOS path PH1 is enabled, and the NMOS path PH2 is disabled.

Next, in the step S220, as shown in the FIGS. 11A, 11C and 11D, a content of the second selection signal SS2 is set and the second selection signal SS2 is provided to the second selection logic circuit SELC2 to disable the CMOS path PH0. For example, second selection signal SS2 is set as “1”. Accordingly, “0” is provided to the PMOS transistor PM0 of the CMOS path PH0 and “1” is provided to the NMOS transistor NM0 of the CMOS path PH0. As such, the CMOS path PH0 is enabled.

Then, in the step S330, as shown in the FIG. 11A, a saturation threshold voltage Vtsat or a saturation drain current Idsat of the semiconductor device 1000 is monitored.

According to the embodiments described above, the testing circuit 1000 is a multi-path adaptive switching (MPAS) device for the Advanced Process Control Monitor (APCM). The testing circuit 1000 includes the PMOS path PH1, the NMOS path PH2 and the CMOS path PH0.

The function of the PMOS path PH1 allows for the accurate measurement of the off-state current Ioff of the semiconductor device DUT1. The PMOS path PH1 is only comprised of the local PMOS transistor PM1 and the global PMOS transistor PM2 which effectively block the leakage currents. When the first selection signal SS1 is set as “1”, only the PMOS path PH1 is selected, hence the off-state current Ioff could be measured through the pad DS.

The function of the NMOS path PH2 enables accurate measurement of the linear threshold voltage Vtlin or the linear drain current Idlin of the semiconductor device DUT1. The NMOS path PH2 is only comprised of the local NMOS transistor NM1 and the global NMOS transistor NM2, which are perfect for passing low voltages. When the first selection signal SS1 is set as “0”, only the NMOS path PH2 is selected, hence the linear threshold voltage Vtlin or the linear drain current Idlin could be measured through the pad DS.

The CMOS path PH0 is an independent path comprised the CMOS transmission gate TG0. The CMOS path PH0 is used for the measurement of the saturation threshold voltage or the saturation drain current. The CMOS transmission gate TG0 serves well to measure high current levels.

Further, the transmission gate aspect ratio in the various paths could be adjusted to suit the desired current/voltage levels of the semiconductor device DUT1.

Moreover, since the PMOS path PH1, the NMOS path PH2 and the CMOS path PH0 are now separated, the global NMOS transistor NM2 and the global PMOS transistor PM2 could reduce the off-state subthreshold leakage current from 41 times to 21 times.

Furthermore, as shown in the FIG. 1, to further reduce this leakage current, the biasing transmission gates TG1, TG2 are implemented such that the Node ND′ and the pad DS could have the same voltage bias. By this means, the leakage current from the off-state transmission gates could be further reduced.

According to one example embodiment, a testing circuit is provided. The testing circuit includes a PMOS path, a NMOS path, a first selection logic circuit, a CMOS path and a second selection logic circuit. The first selection logic circuit is connected to the PMOS path and the NMOS path. The first selection logic circuit is used to select either the PMOS path or the NMOS path. The second selection logic circuit is connected to the CMOS path. The PMOS path includes a local PMOS transistor and a global PMOS transistor. The local PMOS transistor is coupled to an output end of the first selection logic circuit. The global PMOS transistor is coupled to an input end of the first selection logic circuit. The local PMOS transistor and the global PMOS transistor are connected in series.

Based on the testing circuit described in the previous embodiments, the second selection logic circuit is used to enable or disable the CMOS path.

Based on the testing circuit described in the previous embodiments, when an off-state current is monitored, the first selection logic circuit selects the PMOS path and the second selection logic circuit disables the CMOS path.

Based on the testing circuit described in the previous embodiments, when a linear threshold voltage or a linear drain current is monitored, the first selection logic circuit selects the NMOS path and the second selection logic circuit disables the CMOS path.

Based on the testing circuit described in the previous embodiments, when a saturation threshold voltage or a saturation drain current is monitored, the first selection logic circuit selects the PMOS path and the second selection logic circuit enables the CMOS path.

Based on the testing circuit described in the previous embodiments, the testing circuit further comprises two biasing transmission gates.

Based on the testing circuit described in the previous embodiments, the first selection logic circuit includes an AND gate and an OR gate. One input end of the AND gate is used to receive a primary output signal of a D-flip flop. Another input end of the AND gate is connected to an inverter. An output end of the AND gate is connected to the NMOS path. One input end of the OR gate is used to receive a complementary output signal of the D-flip flop. Another input end of the OR gate is connected to the inverter. The inverter is used to receive a first selection signal. An output end of the OR gate is connected to the PMOS path.

Based on the testing circuit described in the previous embodiments, the CMOS path includes a CMOS transmission gate. The CMOS transmission gate is connected to the second selection logic circuit.

Based on the testing circuit described in the previous embodiments, the second selection logic circuit includes a NAND gate and an inverter. One input end of the NAND gate is used to receive a primary output signal of a D-flip flop. Another input end of the NAND gate is used to receive a second selection signal. An input end of the inverter is connected to an output end of the NAND gate. An output end of the inverter is connected to a NMOS transistor of the CMOS transmission gate. A node between the NAND gate and the inverter is connected to a PMOS transistor of the CMOS transmission gate.

According to one example embodiment, a testing method is provided. The testing method includes: setting a content of a first selection signal and providing the first selectin signal to an inverter connected to a first selection logic circuit to select a PMOS path; setting a content of a second selection signal and providing the second selection signal to a second selection logic circuit to disable a CMOS path; and monitoring an off-state current.

Based on the testing method described in the previous embodiments, when the off-state current is monitored, the content of the first selection signal is set as “1” and the content of the second selection signal is set as “0.”

Based on the testing method described in the previous embodiments, the testing method further comprises: setting the content of the first selection signal and providing the first selection signal to the inverter connected to the first selection logic circuit to select the NMOS path; setting the content of the second selection signal and providing the second selection signal to the second selection logic circuit to disable the CMOS path; and monitoring a linear threshold voltage or a linear drain current.

Based on the testing method described in the previous embodiments, when the linear threshold voltage or the linear drain current is monitored, the content of the first selection signal is set as “0” and the content of the second selection signal is set as “0.”

Based on the testing method described in the previous embodiments, the testing method further comprises: setting the content of the first selection signal and providing the first selection signal to the inverter connected to the first selection logic circuit to select the PMOS path; setting the content of the second selection signal and providing the second selection signal to the second selection logic circuit to enable the CMOS path; monitoring a saturation threshold voltage or a saturation drain current.

Based on the testing method described in the previous embodiments, when the saturation threshold voltage or the saturation drain current is monitored, the content of the first selection signal is set as “1” and the content of the second selection signal is set as “1.”

According to one example embodiment, a testing circuit is provided. The testing circuit includes a PMOS path, a NMOS path and a CMOS path. One of the PMOS path and the NMOS path is enabled according to a first selection signal. The PMOS path includes a local PMOS transistor and a global PMOS transistor. The local PMOS transistor and the global PMOS transistor are connected in series.

Based on the testing circuit described in the previous embodiments, the CMOS path is enabled or disabled according to a second selection signal.

Based on the testing circuit described in the previous embodiments, the NMOS path includes a local NMOS transistor and a global NMOS transistor. The local NMOS transistor and the global NMOS transistor are connected in series.

Based on the testing circuit described in the previous embodiments, the testing circuit further comprises two biasing transmission gates.

Based on the testing circuit described in the previous embodiments, the CMOS path includes a CMOS transmission gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A testing circuit, comprising:
a PMOS path;
a NMOS path;
a first selection logic circuit, connected to the PMOS path and the NMOS path;
a CMOS path; and
a second selection logic circuit, connected to the CMOS path, wherein the second selection logic circuit is used to enable or disable the CMOS path, wherein the PMOS path includes:
a local PMOS transistor, coupled to an output end of the first selection logic circuit; and
a global PMOS transistor, coupled to an input end of the first selection logic circuit, wherein the local PMOS transistor and the global PMOS transistor are connected in series.

2. The testing circuit according to claim 1, wherein the first selection logic circuit is used to select either the PMOS path or the NMOS path.

3. The testing circuit according to claim 1, wherein when an off-state current i monitored, the first selection logic circuit selects the PMOS path and the second selection logic circuit disables the CMOS path.

4. The testing circuit according to claim 1, wherein when a linear threshold voltage or a linear drain current is monitored, the first selection logic circuit selects the NMOS path and the second selection logic circuit disables the CMOS path.

5. The testing circuit according to claim 1, wherein when a saturation threshold voltage or a saturation drain current is monitored, the first selection logic circuit selects the PMOS path and the second selection logic circuit enables the CMOS path.

6. The testing circuit according to claim 1, further comprising:
two biasing transmission gates.

7. The testing circuit according to claim 1, wherein the first selection logic circuit includes:
an AND gate, wherein one input end of the AND gate is used to receive a primary output signal of a D-flip flop, another input end of the AND gate is connected to an inverter, and an output end of the AND gate is connected to the NMOS path; and
an OR gate, wherein one input end of the OR gate is used to receive a complementary output signal of the D-flip flop, another input end of the OR gate is connected to the inverter, the inverter is used to receive a first selection signal, and an output end of the OR gate is connected to the PMOS path.

8. The testing circuit according to claim 1, wherein the CMOS path includes:
a CMOS transmission gate, connected to the second selection logic circuit SELC2.

9. The testing circuit according to claim 8, wherein the second selection logic circuit includes:
a NAND gate, wherein one input end of the NAND gate is used to receive a primary output signal of a D-flip flop, and another input end of the NAND gate is used to receive a second selection signal; and
an inverter, wherein an input end of the inverter is connected to an output end of the NAND gate, an output end of the inverter is connected to a NMOS transistor of the CMOS transmission gate, and a node between the NAND gate and the inverter is connected to a PMOS transistor of the CMOS transmission gate.

10. A testing method, comprising:
setting a content of a first selection signal and providing the first selectin signal to an inverter connected to a first selection logic circuit to select a PMOS path;
setting a content of a second selection signal and providing the second selection signal to a second selection logic circuit to disable a CMOS path; and
monitoring an off-state current.

11. The testing method according to claim 10, wherein when the off-state current is monitored, the content of the first selection signal is set as “1” and the content of the second selection signal is set as “0.”

12. The testing method according to claim 10, further comprising:
setting the content of the first selection signal and providing the first selection signal to the inverter connected to the first selection logic circuit to select the NMOS path;
setting the content of the second selection signal and providing the second selection signal to the second selection logic circuit to disable the CMOS path; and
monitoring a linear threshold voltage or a linear drain current.

13. The testing method according to claim 10, wherein when the linear threshold voltage or the linear drain current is monitored, the content of the first selection signal is set as “0” and the content of the second selection signal is set as “0.”

14. The testing method according to claim 10, further comprising:
setting the content of the first selection signal and providing the first selection signal to the inverter connected to the first selection logic circuit to select the PMOS path;
setting the content of the second selection signal and providing the second selection signal to the second selection logic circuit to enable the CMOS path; and
monitoring a saturation threshold voltage or a saturation drain current.

15. The testing method according to claim 14, wherein when the saturation threshold voltage or the saturation drain current is monitored, the content of the first selection signal is set as “1” and the content of the second selection signal is set as “1.”

16. A testing circuit, comprising:
a PMOS path;
a NMOS path, wherein one of the PMOS path and the NMOS path is enabled according to a first selection signal; and
a CMOS path, wherein the PMOS path includes:
a local PMOS transistor; and
a global PMOS transistor, wherein the local PMOS transistor and the global PMOS transistor are connected in series.

17. The testing circuit according to claim 16, wherein the CMOS path is enabled or disabled according to a second selection signal.

18. The testing circuit according to claim 16, wherein the NMOS path includes:
a local NMOS transistor; and
a global NMOS transistor, wherein the local NMOS transistor and the global NMOS transistor are connected in series.

19. The testing circuit according to claim 16, further comprising:
two biasing transmission gates.

20. The testing circuit according to claim 16, wherein the CMOS path includes:
a CMOS transmission gate.
